(19) United States
(12) Patent Application Publication
(10) Pub. No.: US 2012/0241801 A1
(43) Pub. Date: Sep. 27, 2012

(54) FLIP-CHIP LED PACKAGING AND MANUFACTURING THEREOF

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 13/241,286

(22) Filed: Sep. 23, 2011

(30) Foreign Application Priority Data
Mar. 25, 2011 (TW) 100110277

(51) Int. Cl. H01L 33/62; H01L 33/48

(52) U.S. Cl. 257/99; 438/26; 257/E33.062; 257/E33.056

(57) ABSTRACT

A flip-chip LED package includes a transparent substrate, an LED chip and a holder. The transparent substrate is formed by heating a green piece made of a mixture of glass powders and solvent. The LED chip includes a first side and an opposite second side, and two electrodes formed on the first side. The second side of the LED chip is directly attached to the transparent substrate. The holder combines to the LED chip. The holder includes two solders connected to the electrodes of the LED chip respectively. The present disclosure also relates to a method for manufacturing such flip-chip LED package.

### BACKGROUND

1. Technical Field

The present disclosure relates to solid state light emitting devices and, more particularly, to a flip-chip package structure of light emitting diode (LED) and a manufacturing method thereof.

2. Discussion of Related Art

An LED includes a transparent substrate and an LED chip mounted on the transparent substrate by colloid, such as glue. The LED is mounted on a base by flip-chip bonding. However, it needs a high temperature for the flip-chip bonding, which may cause the colloid between the transparent substrate and the LED chip to be melted. When this happens the LED chip will separate from the transparent substrate.

Therefore, there is room for improvement in the art.

### BRIEF DESCRIPTION OF THE DRAWINGS

FIG. 1 is a cross-sectional view of a flip-chip LED package in accordance with an embodiment of the present disclosure.

FIGS. 2 to 5 are cross-sectional views showing different steps of an embodiment of a method for manufacturing the flip-chip LED package.

### DETAILED DESCRIPTION OF EMBODIMENTS

Reference will now be made to the drawings to describe various embodiments of the present flip-chip LED package in detail.

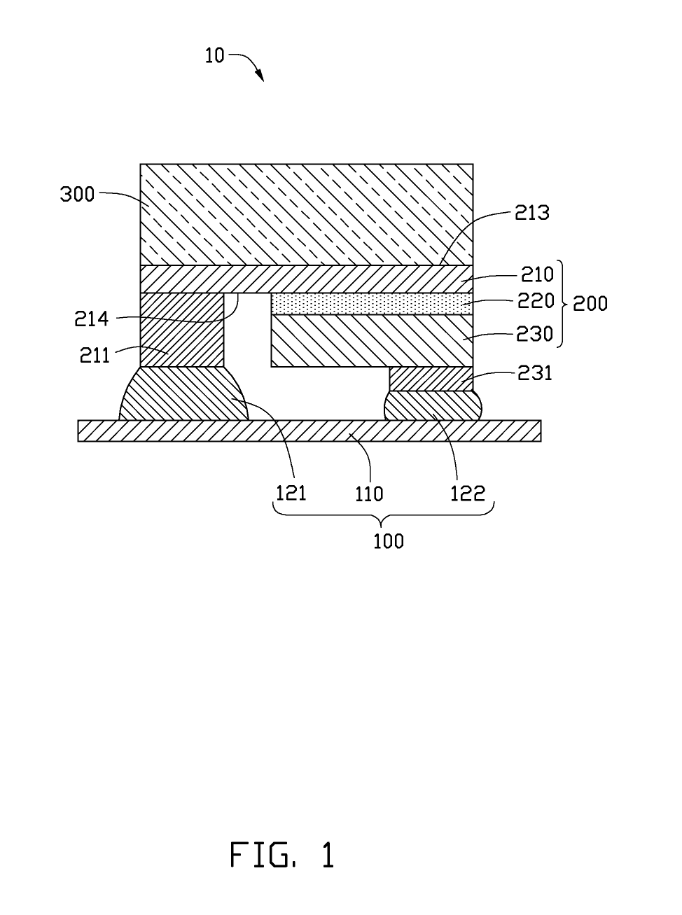

Referring to FIG. 1, a flip-chip LED package 10 in accordance with the present embodiment is provided. The flip-chip LED package 10 includes a holder 100, an LED chip 200 and a transparent substrate 300.

The LED chip 200 includes a first layer 210, an active layer 220, and a second layer 230 arranged in sequence along a direction from the transparent substrate 300 to the holder 100. In the present embodiment, the first layer 210 is a P-type layer, and the second layer 230 is an N-type layer. The first and second layers 210, 230 can be made of a material of AlGaP. The first layer 210 includes a first surface 213 contacting the transparent substrate 300 and a second surface 214 opposite to the first surface 213. Part of the second surface 214 is covered by the active layer 220, and a part of the second surface 214 is exposed with a first electrode 211 formed thereon. A second electrode 231 is formed on a bottom side of the second layer 230 away from the active layer 220.

The transparent substrate 300 beneficially is a single glass plate made of low temperature glass powders, and is directly and integrally formed on the LED chip 200, without any colloid disposed therebetween. In other words, the substrate 300 and the LED chip 200 are combined together to form an inseparable structure, which can be separated only if the substrate 300 and/or the LED chip 200 are damaged or destroyed. A melting temperature of the glass powders ranges from 300 to 500 degrees centigrade. Ceramic powders can be mixed into the glass powders for reinforcing the transparent substrate 300, and adjusting the coefficient of thermal expansion of the transparent substrate 300.

The holder 100 includes a base 110, and an N-type solder 121 and a P-type solder 122 arranged on the base 110. The LED chip 200 is arranged on the base 100 via flip-chip bonding at a temperature range from 150 to 200 degrees centigrade. In the present embodiment, the first electrode 211 of the LED chip 200 is electrically connected to the N-type solder 121, and the second electrode 231 of the LED chip 200 is electrically connected to the P-type solder 122. Since the LED chip 200 and the substrate 300 are directly combined together without any colloid, during the flip-chip bonding, melting of the colloid is avoided, and accordingly separation of the LED chip 200 from the substrate 300 is avoided.

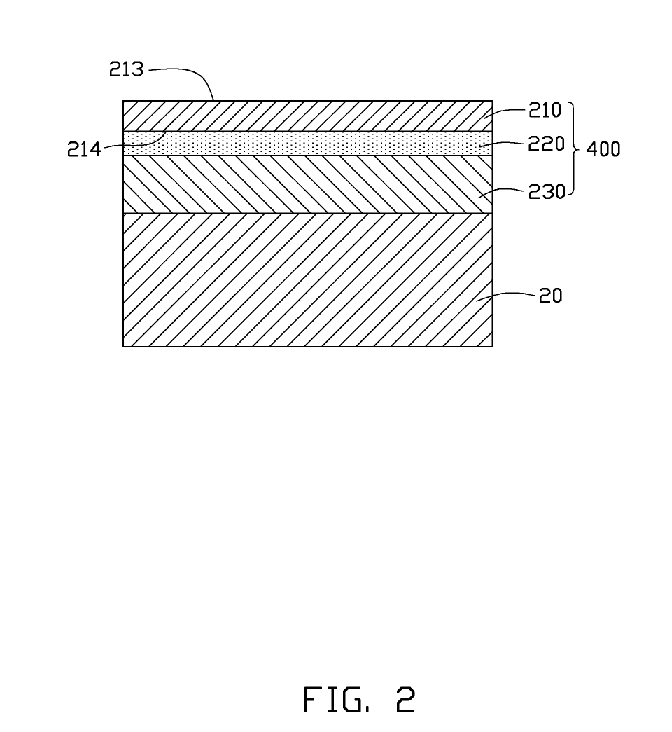

Referring to FIGS. 2 to 5, a method for manufacturing the flip-chip LED package 10 in accordance with the exemplary embodiment is also disclosed, which includes the following steps.

Referring to FIG. 2, the first step is to provide a temporary substrate 20 and epitaxially form a multi-layered semiconductor structure 400 on the temporary substrate 20. In the present embodiment, the temporary substrate 20 preferably is a single crystal plate made of sapphire. The multi-layered semiconductor structure 400 includes a second layer 230, an active layer 220, and a first layer 210 sequentially arranged on the temporary substrate 20 along a direction away from the temporary substrate 20. In the present embodiment, the first layer 210 is a P-type layer, and the second layer 230 is an N-type layer. The first layer 210 includes a first surface 213 away from the active layer 220 and a second surface 214 opposite to the first surface 213.

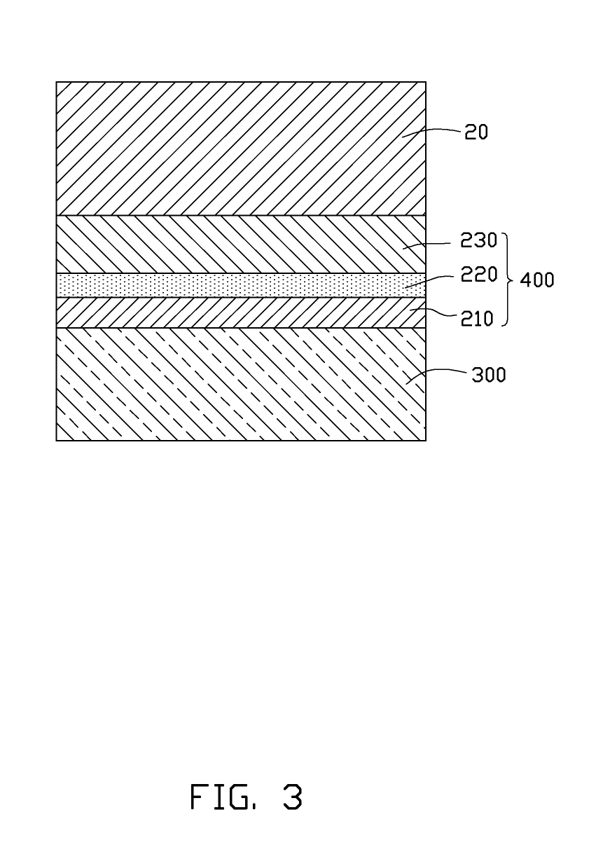

Referring to FIG. 3, the second step is to form a transparent substrate 300 directly on the multi-layered semiconductor structure 400. In the present embodiment, the transparent substrate 300 is a single glass made of low temperature glass powders which are first formed into a plate-like green piece and then heated into a semi-molten state to be fixed directly and integrally on the LED chip 200, without any colloid disposed therebetween. In other words, the substrate 300 and the multi-layered semiconductor structure 400 are combined together to form an inseparable structure, which can be separated only if the substrate 300 and/or the multi-layered semiconductor structure 400 are damaged or destroyed. A melting temperature of the glass powders ranges from 300 to 500 degrees centigrade. Ceramic powders can be mixed into the glass powders for reinforcing the transparent substrate 300, and adjusting the coefficient of thermal expansion of the transparent substrate 300.

In the present embodiment, the glass powders are mixed in organic solvent to form a mixture, and then the mixture is heated to vaporize the organic solvent, thereby forming a green piece of the transparent substrate 300. The green piece of the transparent substrate 300 is then heated into a semi-molten state and thereafter put on first surface 213 of the first layer 210 of the multi-layered semiconductor structure 400 whereby the green piece of the transparent substrate 300 is directly attached and adhered to the first surface 213 of the first layer 210 of the multi-layered semiconductor structure 400. After cooling to a room temperature, the transparent substrate 300 is formed which is integral with the multi-layered semiconductor structure 400. As described above, the glass powders are provided to form the green piece of the transparent substrate 300 firstly, and then the green piece of the transparent substrate 300 and the multi-layered semiconductor structure 400 are combined together. Alternatively, the mixture of the glass powders and organic solvent can be directly coated on the first surface 213 and then heated until the organic solvent is vaporized, thereby directly and integrally forming the green piece of the transparent substrate 300 on the first surface 213 of the multi-layered semiconductor structure 400. Thereafter, the green piece of the transparent substrate 300 is heated to be in a semi-molten state to connect with the multi-layered semiconductor structure 400. After cooling of the green piece of the transparent substrate 300, the transparent substrate 300 is formed, which is firmly connected to the multi-layered semiconductor structure 400.

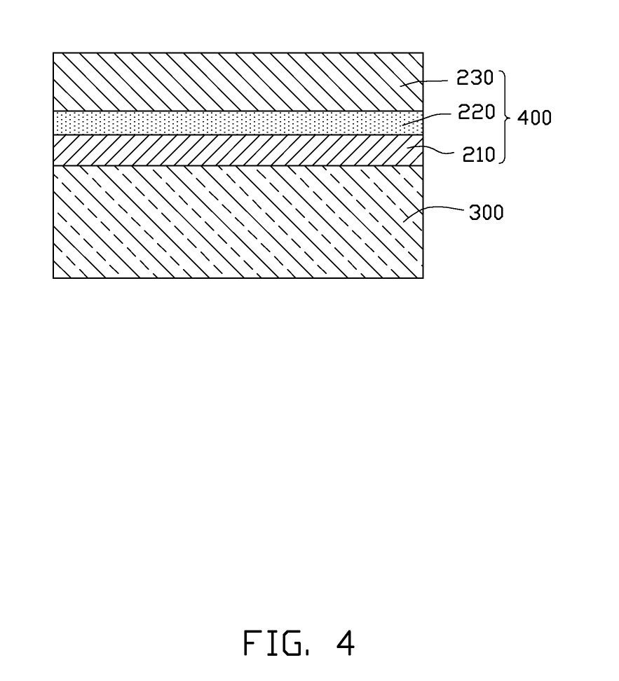

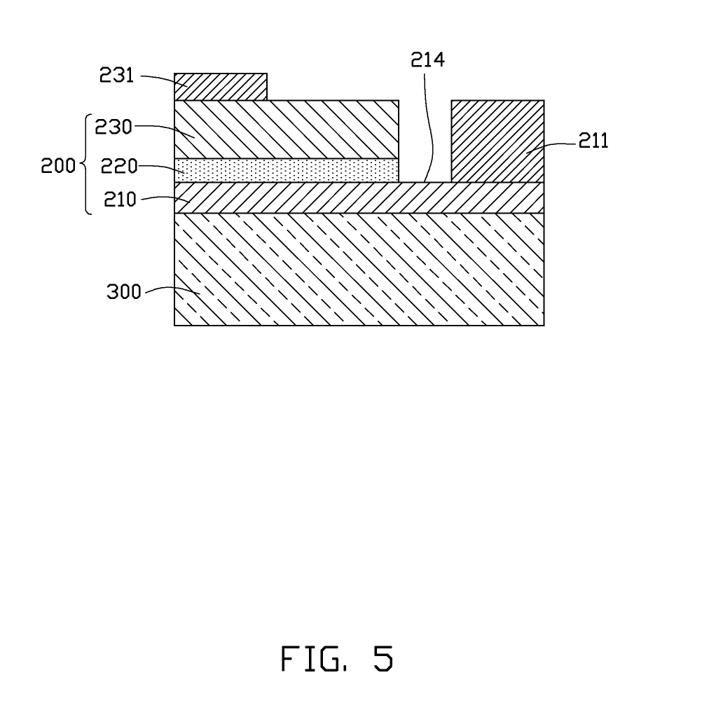

Referring to FIGS. 4 to 5, the third step is to remove the temporary substrate 20 and to etch the multi-layered semiconductor structure 400 to form an LED chip 200. The temporary substrate 20 can be removed via laser ablation, chemical stripping, or mechanical grinding. Parts of the second and active layers 230, 220 of the multi-layered semiconductor structure 400 are etched to form a developed mesa structure, whereby the second surface 214 of the first layer 210 is partially exposed. A first electrode 211 is then formed on the exposed part of the second surface 214 of the first layer 210. A second electrode 231 is formed on the second layer 230 away from the active layer 220.

Referring to FIG. 1 again, the fourth step is to provide a holder 100 having an N-type solder 121 and a P-type solder 122, and mount the LED chip 200 on the holder 100 via flip-chip bonding. The first electrode 211 and the second electrode 231 of the LED chip 200 are electrically connected to the N-type solder 121 and P-type solder 122, respectively.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A flip-chip package structure of light emitting diode (LED), comprising:
a transparent substrate;
an LED chip, the LED chip comprising a first side and an opposite second side, two electrodes being formed on the first side, and the second side of the LED chip being directly attached and secured to the transparent substrate without any interconnecting agent therebetween; and
a holder combined to the LED chip, the holder comprising two solders being connected to the electrodes of the LED chip respectively.

2. The flip-chip LED package of claim 1, wherein the transparent substrate is made of low temperature glass powders, and a melting temperature of the glass powders is in a range from 300 to 500 degrees centigrade.

3. The flip-chip LED package of claim 1, wherein the transparent substrate comprises ceramic powders.

4. The flip-chip LED package of claim 1, wherein the holder comprises a base and the two solders are respectively an N-type solder and a P-type solder arranged on the base.

5. A method for manufacturing a flip-chip LED package comprising:
providing a multi-layered semiconductor structure;
forming and securing a transparent substrate directly on the multi-layered semiconductor structure;
etching the multi-layered semiconductor structure to form an LED chip; and
providing a holder and mounting the LED chip on the holder via flip-chip bonding.

6. The method of claim 5, wherein the step of forming and securing the transparent substrate on the multi-layered semiconductor structure comprising mixing glass powders in organic solvent to form a mixture, heating the mixture to vaporize the organic solvent to form a green piece of the transparent substrate, heating the green piece of the transparent substrate to a semi-molten state and attaching the semi-molten green piece of the transparent substrate to the multi-layered semiconductor structure and then cooling the green piece of the transparent substrate to obtain the transparent substrate directly secured on the multi-layered semiconductor structure.

7. The method of claim 6, wherein ceramic powders are mixed into the glass powders for reinforcing the transparent substrate.

8. The method of claim 5, wherein the step of forming and securing the transparent substrate on the multi-layered semiconductor structure comprising mixing glass powders in organic solvent to form a mixture, coating the mixture directly on the multi-layered semiconductor structure, heating the mixture until the organic solvent is vaporized to form a green piece of the transparent substrate directly on the multi-layered semiconductor structure, heating the green piece of the transparent substrate to a semi-molten stat, and cooling the green piece of the transparent substrate to obtain the transparent substrate formed and secured on the multi-layered semiconductor structure.

9. The method of claim 8, wherein the glass powders are low temperature glass powders, and a melting temperature of the glass powders is in a range from 300 to 500 degrees centigrade.

10. The method of claim 6, wherein the glass powders are low temperature glass powders, and a melting temperature of the glass powders is in a range from 300 to 500 degrees centigrade.
